(19) United States
(12) Patent Application Publication
(10) Pub. No.: US 2024/0288505 A1
(43) Pub. Date: Aug. 29, 2024

(54) Battery Health State Calculation Method and Related Device

(71) Applicant: Autel Digital Power Co., Ltd., Shenzhen (CN)

(72) Inventors: Songsong QU, Shenzhen (CN); Guangwen FENG, Shenzhen (CN)

(73) Assignee: Autel Digital Power Co., Ltd., Shenzhen, GD (CN)

(21) Appl. No.: 18/570,650

(22) PCT Filed: Jun. 1, 2022
(86) PCT No.: PCT/CN2022/096655

§ 371 Date: Dec. 15, 2023

(30) Foreign Application Priority Data
Jun. 17, 2021 (CN) 202110674720.6

(51) Int. Cl. G01R 31/392; B60L 53/62; B60L 53/65; B60L 53/66; G01R 31/388

(52) U.S. Cl. CPC G01R 31/392; B60L 53/62; B60L 53/65; B60L 53/66; G01R 31/388

(57) ABSTRACT

A battery health state calculation method includes: acquiring vehicle information of a vehicle to be charged in response to a charging start operation; determining a target battery capacity of the vehicle to be charged according to the vehicle information; acquiring a charging parameter of the charging device and SOC information of the vehicle to be charged in a target charging period in response to a charging end operation; the target charging period including a time period between the charging start operation and the charging end operation; and determining a battery health state of the vehicle to be charged according to the charging parameter, the SOC information, and the target battery capacity. Through the above manner, the embodiments of the present invention improve the determination efficiency of the battery health state.

The present application claims priority to the Chinese patent application No. 202110674720.6 entitled “Battery Health State Calculation Method and Related Device” filed on Jun. 17, 2021, to the China National Intellectual Property Administration, the entire contents of which are incorporated herein by reference.

### TECHNICAL FIELD

Embodiments of the present invention relate to the technical field of new energy automobiles, and specifically to a battery health state calculation method and a related device.

### BACKGROUND OF THE INVENTION

In a new energy automobile, a battery provides a power source for the automobile, which determines the maximum mileage of the new energy automobile. With the use of the new energy automobile, the battery capacity will attenuate, and the state of health (SOH) of the battery will become lower and lower. Therefore, the health state of the battery is crucial for the use and maintenance of the new energy automobile.

However, the inventors have found during the implementation of the prior art that: the battery health state in the prior art is generally estimated by using a big data sample or the battery is subjected to charging and discharging tests in a laboratory to simulate and calculate the battery life. However, the cost of big data samples is high, and the accuracy of laboratory simulation calculation is low. Therefore, there is a need for a more efficient and accurate battery health state calculation method.

### SUMMARY OF THE INVENTION

In view of the above problem, the embodiments of the present invention provide a battery health state calculation method and a related device for solving the problem of low efficiency of battery health state calculation for new energy automobiles existing in the prior art.

According to one aspect of an embodiment of the present invention, there is provided a battery health state calculation method applied to a charging device. The method comprises:
acquiring vehicle information of a vehicle to be charged in response to a charging start operation;
determining a target battery capacity of the vehicle to be charged according to the vehicle information;
acquiring, in response to the charging end operation, a charging parameter of the charging device and SOC information of the vehicle to be charged within a target charging period, the target charging period including a time period between the charging start operation and the charging end operation;
and determining the battery health state of the vehicle to be charged according to the charging parameter, the SOC information, and the target battery capacity.

In an alternative manner, the vehicle information comprises a VIN code; the method further comprises:
determining manufacturer information, vehicle type information, and the production time of the vehicle to be charged according to the VIN code;
determining an initial battery capacity of the vehicle to be charged according to the manufacturer information, vehicle type information, and production time;
determining a time interval between the production time and the time of the charging start operation;
and determining the target battery capacity according to the time interval, vehicle information, and initial battery capacity.

In an alternative manner, the method further comprises:
determining a battery attenuation curve of the vehicle to be charged according to the vehicle information, the battery attenuation curve comprising correspondence between battery attenuation information and battery usage time;
determining target attenuation information according to the time interval and the battery capacity attenuation curve;
and determining the target battery capacity according to the target attenuation information and the initial battery capacity.

In an alternative manner, the charging parameters include a charging current and charging time, and the SOC information includes a first SOC corresponding to the starting time of the target charging period and a second SOC corresponding to the end time of the target charging period for the vehicle to be charged, the method further comprises:
performing a calculation according to the charging current and the charging time to obtain a charging electric quantity corresponding to the target charging period;
determining the SOC change amount of the vehicle to be charged in the target charging period according to the first SOC and the second SOC;
and determining the battery health state of the vehicle to be charged according to the charging electric quantity, the SOC change amount, and the target battery capacity.

In an alternative manner, the method further comprises:
determining a product of the target battery capacity and the SOC change amount as a battery-received electric quantity;
and determining the battery health state according to a specific value of the charging electric quantity to the battery-received electric quantity.

In an alternative manner, the method further comprises:
determining whether the charging current meets a current threshold;
and if so, determining the second SOC according to a SOC charging current curve, wherein the SOC charging current curve comprises a correspondence between the SOC and the charging current, and the SOC charging current curve is determined according to the vehicle information.

In an alternative manner, the method further comprises:
determining the charging efficiency of the vehicle to be charged according to the vehicle information;
and performing a calculation on the charging efficiency, the charging current, and the charging time to obtain the charging electric quantity.

According to another aspect of an embodiment of the present invention, there is provided a battery health state calculation device, including:
a processor, a memory, a communication interface, and a communication bus, the processor, the memory, and the communication interface completing communication with each other through the communication bus;
and the memory being used for storing at least one executable instruction that causes the processor to execute an operation of the battery health state calculation method.

According to yet another aspect of an embodiment of the present invention, there is provided a computer-readable storage medium storing therein at least one executable instruction for causing a battery health calculation device to execute the operation of the battery health state calculation method.

According to still another aspect of an embodiment of the present invention, there is provided a charging pile including the battery health state calculation device.

In an alternative manner, the charging pile further comprises a VCI device for acquiring the vehicle information and the SOC information.

An embodiment of the present invention is applied to a charging device that acquires vehicle information of a vehicle to be charged by responding to a charging start operation; determines a target battery capacity of the vehicle to be charged according to the vehicle information; acquires a charging parameter of the charging device and SOC information of the vehicle to be charged in a target charging period in response to a charging end operation; the target charging period including a time period between the charging start operation and the charging end operation; and finally, determines a battery health state of the vehicle to be charged according to the charging parameter, the SOC information, and the target battery capacity.

An embodiment of the present invention directly acquires, in real time, a charging parameter of a target charging period and SOC information about a vehicle to be charged via a charging device, and determines its battery health state according to the SOC information and the charging parameter and a target battery capacity corresponding to the vehicle to be charged. Therefore, it can overcome the technical defect that the calculation efficiency of the battery health state is low due to the big data model or laboratory simulation adopted in the prior art, thereby improving the efficiency of the calculation of the battery health state.

The above description is only an overview of the technical schemes of the embodiments of the invention. In order to understand the technical means of the embodiments of the invention more clearly, it can be implemented according to the contents of the description. In order to make the above and other purposes, features, and advantages of the embodiments of the invention more obvious and understandable, specific implementation modes of the invention are listed below.

### BRIEF DESCRIPTION OF DRAWINGS

The drawings are only for the purpose of illustrating the implementation modes and are not to be construed as limiting the present invention. Moreover, like reference numerals denote like components throughout the drawings. In the drawings:

FIG. 1 is a schematic flow chart illustrating a battery health state calculation method provided by an embodiment of the present invention;

FIG. 2 shows a schematic view of a module of a battery health state calculation system provided by an embodiment of the present invention;

FIG. 3 is a schematic view showing a structure of a battery health state calculation device provided by an embodiment of the present invention.

### DETAILED DESCRIPTION OF THE INVENTION

Hereinafter, exemplary embodiments of the present invention will be described in more detail with reference to the accompanying drawings. While the drawings show exemplary embodiments of the invention, it should be understood that the invention may be implemented in various forms and should not be limited by the embodiments described herein.

A Before the description of the battery health state calculation method according to an embodiment of the present invention, explanations of relevant terms are made as follows:
VCI: Vehicle Communication Interface, a vehicle communication interface, is used to connect to a communication interface of a vehicle-mounted diagnostic system so as to acquire information about each ECU (Electronic Control Unit) module in a vehicle-mounted control system;
SOC: State Of Charge, SOC can be determined according to the ampere-hour integral method, open circuit voltage method, etc. and is generally expressed in the form of a percentage, so as to characterize the proportion of the current battery capacity to the battery capacity when the battery is fully charged;
SOH: that is, the State Of Health, the battery health state, characterizes the charging and discharging capacity of the battery; and
Vin Code: that is, the Vehicle Identification Number, the abbreviation of vehicle identification number, is a group of seventeen letters or numbers used for specifically marking the number of a vehicle, and can be used for identifying the manufacturer, engine, chassis serial number, other performances, and like information of an automobile.

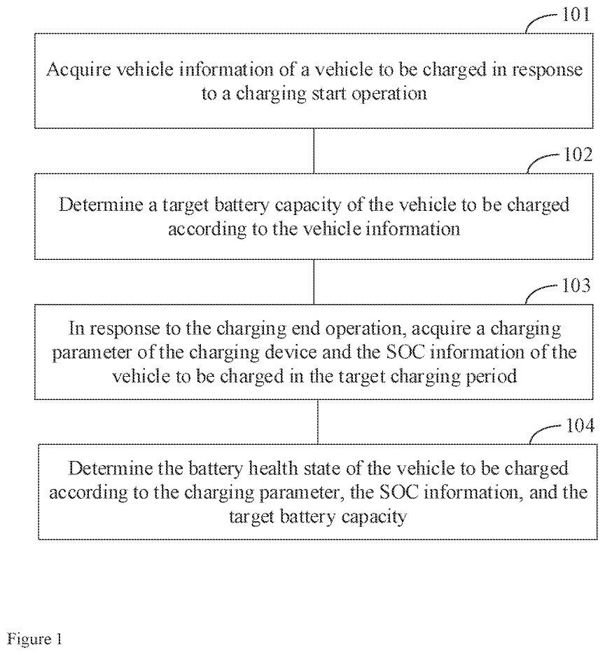

FIG. 1 shows a flowchart of a battery health state calculation method provided by an embodiment of the present invention, and the method is executed by a computer processing device. The computer processing device may include a charging pile, a charging cabinet, etc. The battery health state calculation method is described below by taking a charging device as a charging pile: as shown in FIG. 1, the method comprises the following steps:
step 101: in response to the charging start operation, acquiring the vehicle information of a vehicle to be charged.

In one embodiment of the invention, the charging start operation may be an operation in which the charging gun detected by the charging device establishes an electrical connection with the charging interface of the vehicle to be charged. A charging gun is provided on the charging pile for outputting alternating current or direct current electric energy. The vehicle to be charged may be an electric automobile, an electric vehicle or like devices that include a storage battery.

In one embodiment of the present invention, the vehicle information comprises information such as a VIN code, a license plate number, a vehicle model, a vehicle manufacturer, delivery time, and an associated account number; the associated account number may comprise a mobile phone number, a social platform account number, a charging platform account number, etc. associated with the vehicle to be charged; the charging platform is used for managing the charging device.

In still another embodiment of the present invention, the above-mentioned vehicle information may be acquired by accessing an OBD interface of a vehicle to be charged through a VCI device, wherein the VCI device is connected to the charging device in a common wireless or wired manner, the wireless manner including WIFI, Bluetooth, etc. While the charging gun is connected to the vehicle to be charged, the VCI device establishes a communication connection with the OBD interface of the vehicle to be charged to which the charging gun is connected.

In still another embodiment of the present invention, the vehicle information may also be acquired by the charging device accessing a pre-set vehicle information platform, wherein the charging device is wirelessly connected to the vehicle information platform, and the vehicle information platform stores vehicle information corresponding to multiple VIN codes or license plate numbers. Alternatively, the vehicle information may also be acquired by the charging device performing a query based on the pre-stored vehicle database including therein the vehicle information of a historically charged vehicle having established a connection with the charging device.
Step 102: determine the target battery capacity of the vehicle to be charged according to the vehicle information.

In one embodiment of the invention, the target battery capacity comprises a rated battery capacity of the vehicle to be charged at the time of the vehicle leaving the factory, which may characterize the ideal battery capacity of the vehicle to be charged when the battery health is not impaired.

In still another embodiment of the present invention, considering that there may be a certain natural loss in the battery capacity as the delivery time passes, in this case, if the rated battery capacity calibrated by the vehicle manufacturer at the time of delivery is still taken as the target battery capacity, it is inaccurate. Therefore, the accuracy of the calculation of the battery health state will be reduced. So step 102 may further comprise:
step 1021: determining manufacturer information, vehicle type information, and the production time of the vehicle to be charged according to the VIN code.

In one embodiment of the present invention, a query may be made in a vehicle database pre-stored in a charging device according to a VIN code, wherein the vehicle database includes therein multiple VIN codes and manufacturer information, vehicle type information, and production time associated with each VIN code.

In still another embodiment of the present invention, it may also be possible that after acquiring the VIN code, the charging device sends the VIN code to the vehicle information platform for query, and determines the manufacturer information, vehicle type information, and production time of the vehicle to be charged according to the information returned by the vehicle information platform.
Step 1022: determine the initial battery capacity of the vehicle to be charged according to the manufacturer information, vehicle type information, and production time.

In one embodiment of the present invention, the initial battery capacity may be determined by performing a table lookup based on the manufacturer information and the vehicle type information.

In still another embodiment of the present invention, considering the upgrade of products or the adjustment of technical parameters, etc. it is also possible to determine the production batch of the vehicle to be charged on the basis of the manufacturer information and the vehicle type information in combination with the production time, so as to perform a query according to the generation batch and determine the initial battery capacity.
Step 1023: determine a time interval between the production time and the time of the charging start operation.

By way of example, the time of the charging start operation may be the time at which the connection of a charging inserting gun of the charging pile with the charging interface of the vehicle to be charged is detected, e.g. 2021.5.14 15:00:00, and the production time may be 2019.5.14, so that the time interval is 2 years.
Step 1024: determine the target battery capacity according to the time interval, vehicle information, and initial battery capacity.

In one embodiment of the present invention, attenuation characteristic information that the initial battery capacity of the vehicle to be charged attenuates with time after leaving the factory is determined based on the vehicle information, and a capacity attenuation duration is determined based on the time interval, so that the target battery capacity is determined based on the initial battery capacity according to the attenuation characteristic information and the capacity attenuation duration. The attenuation characteristic information may comprise an attenuation ratio per unit time, an attenuation quantity per unit time, etc.

Therefore, in yet another embodiment of the present invention, step 1024 further comprises at least:
step 241: determining a battery attenuation curve of the vehicle to be charged according to the vehicle information; the battery attenuation curve including correspondence between the battery attenuation information and battery usage time.

In one embodiment of the invention, the battery attenuation curve may be obtained by performing learning according to big data of vehicles of the same type as the vehicle to be charged. The same type of vehicle includes a vehicle of the same manufacturer and the same vehicle model as the vehicle to be charged.

Battery attenuation information may include battery capacity attenuation value, battery capacity attenuation ratio, etc. The battery usage time may be calculated starting from the vehicle leaving the factory, or may be obtained by performing conversion according to the mileage traveled by the vehicle.
Step 242: determine the target attenuation information according to the time interval and the battery capacity attenuation curve.

In one embodiment of the present invention, the time interval is taken as the target battery usage time, and the battery attenuation information corresponding to the target battery usage time is determined as the target attenuation information on the battery attenuation curve.
Step 243: determine the target battery capacity according to the target attenuation information and the initial battery capacity.

For example, the target attenuation information may be that the battery capacity attenuation rate is 10/a, the initial battery capacity may be 50 Ah, and then the target battery capacity is 50*(1-10%)=45 Ah.
Step 103: in response to the charging end operation, acquire a charging parameter of the charging device and the SOC information of the vehicle to be charged in the target charging period.

In one embodiment of the invention, the charging end operation may be an operation detected by the charging device in which the charging gun is electrically disconnected from the charging interface of the vehicle to be charged. The target charging period includes a time period between the charging start operation and the charging end operation.

By way of example, the time corresponding to the charging start operation may be 2021.5.14 15:00:00, the time corresponding to the charging end operation may be 2021.5.14 17:00:00, and the target charging period may be any time period of two hours of 2021.5.14 15:00:00-17:00:00.

In still another embodiment of the present invention, in order to ensure the accuracy of the computation, the duration of the target charging period may be limited, such as being greater than half an hour, or the interval position of the target charging period in the whole charging process may be defined, such as a time period of a preset duration before the charging end operation, or the constant-current charging stage and the constant-voltage charging stage in the charging process may be determined according to a charging parameter, and either end of the constant-current charging stage and the constant-voltage charging stage may be determined as the target charging period.
Step 104: determine the battery health state of the vehicle to be charged from the charging parameter, the SOC information, and the target battery capacity.

In one embodiment of the present invention, the battery state change information of the vehicle to be charged in the target charging period is determined according to the SOC information, thereby determining the chemical energy actually stored by the vehicle to be charged in the target charging period. The electric energy actually output by the charging pile in the target charging period is then determined according to the charging parameter. Finally, the specific value between the above-mentioned actually output electric energy and the actually stored chemical energy is determined as the battery health state.

In yet another embodiment of the present invention, the charging parameter includes a charging current and charging time; the SOC information comprises a first SOC corresponding to the starting time of the target charging period and a second SOC corresponding to the end time of the target charging period of the vehicle to be charged; step 104 further includes at least:
step 1041: performing a calculation according to the charging current and the charging time to obtain a charging electric quantity corresponding to the target charging period.

In one embodiment of the present invention, the charging time is integrated according to the charging current to obtain the charging electric quantity in the target charging period.

Considering that there is a certain internal resistance of the battery, a battery will generate heat during the charging process, so a part of the electric energy output by the charging device will be converted into heat energy dissipation, and the output of the charging device comprises both alternating current and direct current. However, there is generally a certain energy loss when the alternating current is stabilized as direct current and is input into the vehicle to be charged. Therefore, in a further embodiment of the present invention, step 1041 further comprises at least:
step 411: determining the charging efficiency of the vehicle to be charged according to the vehicle information.

In one embodiment of the invention, the charging efficiency refers to the energy conversion efficiency of the electric energy output by the charging pile during a charging process being converted into the chemical energy stored in the battery.

Determining the charging efficiency according to the vehicle information may be acquiring a corresponding charging efficiency parameter according to the manufacturer information and the vehicle type information. The charging efficiency parameter is typically calculated and provided by the manufacturer prior to the delivery of vehicles of each vehicle model. The charging efficiency is typically between 95% and 80%.

In still another embodiment of the present invention, in the case where the manufacturer does not provide the charging efficiency, it is also possible to acquire the big data of the charging process of a vehicle of the same type as the vehicle to be charged described in step 241, and perform a calculation according to the big data of the charging process to obtain the charging efficiency.
Step 412: perform a calculation according to the charging efficiency, the charging current, and the charging time to obtain the charging electric quantity.

In one embodiment of the present invention, the ampere-hour integral method may be used to calculate the charging electric quantity. The computation formula is as follows:

$$\text{?} = {{\int }_{{t}_{0}}}^{{t}_{1}} η I \cdot \text{?}$$

$$\text{?} \text{indicates text missing or illegible when filed}$$

where η is the charging efficiency, I is the charging current, t0 is the time when the target charging period starts, t1 is the time when the target charging period ends, and d_{τ} represents the integration of I to time.
Step 1042: determine the SOC change amount of the vehicle to be charged in the target charging period according to the first SOC and the second SOC.

In one embodiment of the invention, SOC change amount=the second SOC−the first SOC.

In still another embodiment of the present invention, the determining process of the SOC change amount may further include:
step 421: determining whether the charging current satisfies a current threshold.

In one embodiment of the invention, the current threshold may be determined according to the big data of a vehicle of the same type as the vehicle to be charged as described in step 241. The current threshold is used to characterize the change between the charging current output by the charging pile and the SOC of the vehicle to be charged satisfying a certain functional rule, such as a linear relationship, an exponential relationship, etc.
Step 422: if so, determine the second SOC according to the SOC charging current curve.

In one embodiment of the invention, the SOC charging current curve comprises a correspondence between the SOC and the charging current; the SOC charging current curve is determined according to the vehicle information.

In yet another embodiment of the present invention, the SOC charging current curve may be determined by performing learning by acquiring big data of a vehicle of the same type as described in step 241 according to the vehicle information.
Step 1043: determine the battery health state of the vehicle to be charged according to the charging electric quantity, the SOC change amount, and the target battery capacity.

In one embodiment of the invention, the electric quantity output by the charging pile is determined from the charging electric quantity, the theoretically supposedly increased (i.e. received from the charging pile and stored) battery capacity of the vehicle to be charged is determined from the SOC change amount in combination with the target battery capacity, and finally, the specific value of the output electric quantity to the theoretically supposedly increased electric quantity is determined as the battery health state of the vehicle to be charged.

Therefore, in yet another embodiment of the present invention, step 1043 further comprises at least:
step 431: determining a product of the target battery capacity and the SOC change amount as a battery-received electric quantity.

For example, the target battery capacity is 45 Ah, the SOC change amount is 80%, and the battery-received electric quantity is 45 Ah*80%=36 Ah.
Step 432: determine the battery health state according to a specific value of the charging electric quantity to the battery-received electric quantity.

If the charging electric quantity is 32 Ah, the battery health state is charging electric quantity/battery-received electric quantity, i.e. 32 Ah/36 Ah=88.9%.

In yet another embodiment of the present invention, after determining the battery health state, the battery health state may also be demonstrated via a preset display apparatus.

The display apparatus may be a display screen provided on the charging pile or a mobile terminal associated with the vehicle to be charged. The mobile terminal may include a mobile phone, a vehicle-mounted display device, a smart watch, etc.

In still another embodiment of the present invention, the vehicle information acquired in step 101 further includes associated device information by which a communication connection between the charging pile and the mobile terminal is established so as to send the battery health state to the associated mobile terminal device for demonstration.

In yet another embodiment of the present invention, the charging pile may further receive a charging control instruction of an associated mobile terminal, and perform the management on the charging process according to the charging control instruction. For example, the charging control instruction may include charging mode information. The charging mode information may include a quick charging mode, a healthy charging mode, etc. The charging pile adjusts a charging parameter according to charging mode information.

In yet another embodiment of the present invention, the charging pile may also determine a target charging current, a target charging duration, a target charging mode, etc. according to the battery health state, so as to charge the vehicle to be charged in a manner that is most efficient and most beneficial to the battery health.

The battery health calculation method provided by an embodiment of the invention acquires the SOC information of the vehicle to be charged and the charging parameter of the target charging period, and determines its battery health state according to the charging parameter and SOC information and the target battery capacity corresponding to the vehicle to be charged. Therefore, it can overcome the technical defect that the calculation efficiency of the battery health state is low due to the big data model or laboratory simulation adopted in the prior art, thereby improving the efficiency of the calculation of the battery health state.

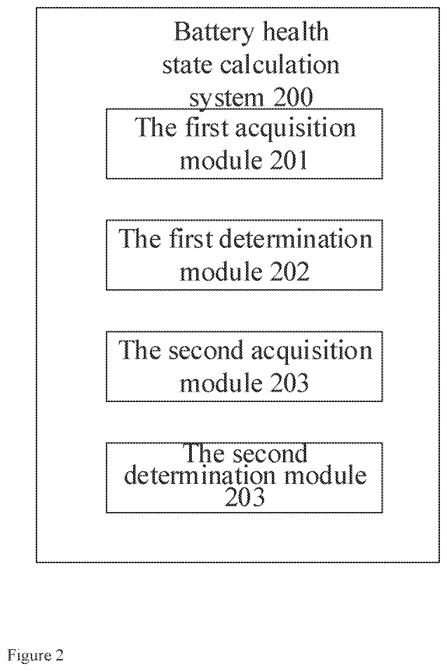

FIG. 2 shows a schematic view of a module of a battery health state calculation system provided by an embodiment of the present invention. As shown in FIG. 2, the battery health state calculation system 200 is one or more program modules that are stored in the memory and executed by one or more processors to complete the present application. The module in this application refers to a series of computer program instruction segments that can complete a specific function. The battery health state calculation system 200 comprises: a first acquisition module 201, a first determination module 202, a second acquisition module 203, and a second determination module 204.

The first acquisition module 201 is used for acquiring vehicle information of a vehicle to be charged in response to a charging start operation;
the first determination module 202 is used for determining a target battery capacity of the vehicle to be charged according to the vehicle information;
the second acquisition module 203 is used for acquiring, in response to the charging end operation, a charging parameter of the charging device and SOC information of the vehicle to be charged within a target charging period, the target charging period including a time period between the charging start operation and the charging end operation;
the second determination module 204 is used for determining the battery health state of the vehicle to be charged according to the charging parameter, the SOC information, and the target battery capacity.

In an alternative manner, the vehicle information comprises a VIN code; the first determination module 202 is also used for determining manufacturer information, vehicle type information, and the production time of the vehicle to be charged according to the VIN code;
determining an initial battery capacity of the vehicle to be charged according to the manufacturer information, vehicle type information, and production time;
determining a time interval between the production time and the time of the charging start operation;
and determining the target battery capacity according to the time interval, vehicle information, and initial battery capacity.

In an alternative manner, the first determination module 202 is further used for:
determining a battery attenuation curve of the vehicle to be charged according to the vehicle information, the battery attenuation curve comprising correspondence between battery attenuation information and battery usage time;
determining target attenuation information according to the time interval and the battery capacity attenuation curve;
and determining the target battery capacity according to the target attenuation information and the initial battery capacity.

In an alternative manner, the charging parameters include a charging current and charging time, and the SOC information includes a first SOC corresponding to the starting time of the target charging period and a second SOC corresponding to the end time of the target charging period for the vehicle to be charged; the first determination module 204 is also used for:
performing a calculation according to the charging current and the charging time to obtain a charging electric quantity corresponding to the target charging period;
determining the SOC change amount of the vehicle to be charged in the target charging period according to the first SOC and the second SOC;
and determining the battery health state of the vehicle to be charged according to the charging electric quantity, the SOC change amount, and the target battery capacity.

In an alternative manner, the second determination module 204 is further used for:
determining a product of the target battery capacity and the SOC change amount as a battery-received electric quantity;
and determining the battery health state according to a specific value of the charging electric quantity to the battery-received electric quantity.

In an alternative manner, the second determination module 204 is further used for:
determining whether the charging current meets a current threshold;
and if so, determining the second SOC according to a SOC charging current curve, wherein the SOC charging current curve comprises a correspondence between the SOC and the charging current, and the SOC charging current curve is determined according to the vehicle information.

In an alternative manner, the second determination module 204 is further used for:
determining the charging efficiency of the vehicle to be charged according to the vehicle information;
and performing a calculation on the charging efficiency, the charging current, and the charging time to obtain the charging electric quantity.

The battery health calculation system provided by an embodiment of the invention acquires the SOC information of the vehicle to be charged and the charging parameter of the target charging period, and determines its battery health state according to the charging parameter and SOC information and the target battery capacity corresponding to the vehicle to be charged. Therefore, it can overcome the technical defect that the calculation efficiency of the battery health state is low due to the big data model or laboratory simulation adopted in the prior art, thereby improving the efficiency of the calculation of the battery health state.

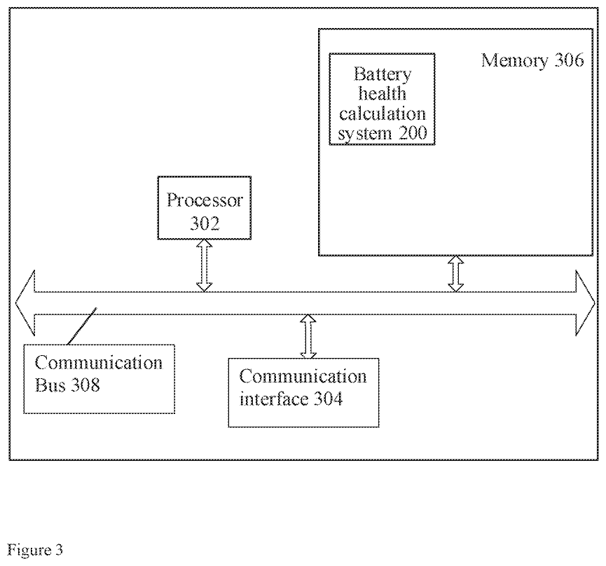

FIG. 3 is a schematic view showing a structure of a battery health state calculation device provided by an embodiment of the present invention. A specific embodiment of the present invention does not limit the specific implementation of the battery health state calculation device.

As shown in FIG. 3, the battery health state calculation device may include: a processor 302, a communication interface 304, a memory 306, and a communication bus 308.

Wherein: The processor 302, the communication interface 304, and the memory 306 communicate with each other through the communication bus 308. The communication interface 304 is used for communicating with network elements of other devices, such as a client, or other servers, etc. The processor 302 is configured to execute the battery health state calculation system 20. Specifically, it can execute relevant steps for an embodiment of the battery health state calculation method.

Specifically, the battery health state calculation system 200 may include one or more program modules (see FIG. 2) composed of a program code that includes a computer-executable instruction.

The processor 302 may be a central processor CPU, or a specific integrated circuit ASIC (Application Specific Integrated Circuit), or one or more integrated circuits configured to implement an embodiment of the present invention. The battery health state calculation device comprises one or more processors, which may be the same type of processor, such as one or more CPUs; or may also be processors of different types, such as one or more CPUs and one or more ASICs.

The memory 306 is used for storing a state-of-health calculation program constituting the battery health state calculation system 200. The memory 306 may include a high-speed RAM memory, and may also include a non-volatile memory, such as at least one magnetic disk memory.

The state-of-health calculation program constituting the battery health state calculation system 200 can be specifically called by the processor 302 to cause the battery health state calculation device to execute the following operations:
acquiring vehicle information of a vehicle to be charged in response to a charging start operation;
determining a target battery capacity of the vehicle to be charged according to the vehicle information;
acquiring, in response to the charging end operation, a charging parameter of the charging device and SOC information of the vehicle to be charged within a target charging period, the target charging period including a time period between the charging start operation and the charging end operation;
and determining the battery health state of the vehicle to be charged according to the charging parameter, the SOC information, and the target battery capacity.

In an alternative manner, the vehicle information comprises a VIN code; the state-of-health calculation program constituting the battery health state calculation system 200 is called by the processor 302 to cause the battery health state calculation device to execute the following operations:
determining manufacturer information, vehicle type information, and the production time of the vehicle to be charged according to the VIN code;
determining an initial battery capacity of the vehicle to be charged according to the manufacturer information, vehicle type information, and production time;
determining a time interval between the production time and the time of the charging start operation;
and determining the target battery capacity according to the time interval, vehicle information, and initial battery capacity.

In an alternative manner, the state-of-health calculation program constituting the battery health state calculation system 200 is called by the processor 302 to cause the battery health state calculation device to execute the following operations:
determining a battery attenuation curve of the vehicle to be charged according to the vehicle information; the battery attenuation curve comprising correspondence between battery attenuation information and battery usage time;
determining target attenuation information according to the time interval and the battery capacity attenuation curve;
and determining the target battery capacity according to the target attenuation information and the initial battery capacity.

In an alternative manner, the charging parameters include a charging current and charging time, and the SOC information includes a first SOC corresponding to the starting time of the target charging period and a second SOC corresponding to the end time of the target charging period for the vehicle to be charged; the state-of-health calculation program constituting the battery health state calculation system 200 is called by the processor 302 to cause the battery health state calculation device to execute the following operations:
performing a calculation according to the charging current and the charging time to obtain a charging electric quantity corresponding to the target charging period;
determining the SOC change amount of the vehicle to be charged in the target charging period according to the first SOC and the second SOC;
and determining the battery health state of the vehicle to be charged according to the charging electric quantity, the SOC change amount, and the target battery capacity.

In an alternative manner, the state-of-health calculation program constituting the battery health state calculation system 200 is called by the processor 302 to cause the battery health state calculation device to execute the following operations:
determining a product of the target battery capacity and the SOC change amount as a battery-received electric quantity;
and determining the battery health state according to a specific value of the charging electric quantity to the battery-received electric quantity.

In an alternative manner, the code program constituting the battery health state calculation system 200 is called by the processor 302 to cause the battery health state calculation device to execute the following operations:
determining whether the charging current meets a current threshold;
and if so, determining the second SOC according to a SOC charging current curve, wherein the SOC charging current curve comprises a correspondence between the SOC and the charging current, and the SOC charging current curve is determined according to the vehicle information.

In an alternative manner, the state-of-health calculation program constituting the battery health state calculation system 200 is called by the processor 302 to cause the battery health state calculation device to execute the following operations:
determining the charging efficiency of the vehicle to be charged according to the vehicle information;
and performing a calculation on the charging efficiency, the charging current, and the charging time to obtain the charging electric quantity.

The battery health calculation device provided by an embodiment of the invention acquires the SOC information of the vehicle to be charged and the charging parameter of the target charging period, and determines its battery health state according to the charging parameter and SOC information and the target battery capacity corresponding to the vehicle to be charged. Therefore, it can overcome the technical defect that the calculation efficiency of the battery health state is low due to the big data model or laboratory simulation adopted in the prior art, thereby improving the efficiency of the calculation of the battery health state.

An embodiment of the present invention provides a computer-readable storage medium storing at least one executable instruction which, when run on a battery health state calculation device, causes the battery health state calculation device to execute the battery health state calculation method of any of the method embodiments described above.

The executable instruction can be specifically used to make the battery health state calculation device execute the following operations:
acquiring vehicle information of a vehicle to be charged in response to a charging start operation;
determining a target battery capacity of the vehicle to be charged according to the vehicle information;
acquiring, in response to the charging end operation, a charging parameter of the charging device and SOC information of the vehicle to be charged within a target charging period, the target charging period including a time period between the charging start operation and the charging end operation;
and determining the battery health state of the vehicle to be charged according to the charging parameter, the SOC information, and the target battery capacity.

In an alternative manner, the vehicle information comprises a VIN code; the executable instruction causes the battery health state calculation device to execute the following operations:
determining manufacturer information, vehicle type information, and the production time of the vehicle to be charged according to the VIN code;
determining an initial battery capacity of the vehicle to be charged according to the manufacturer information, vehicle type information, and production time;
determining a time interval between the production time and the time of the charging start operation;
and determining the target battery capacity according to the time interval, vehicle information, and initial battery capacity.

In an alternative manner, the executable instruction causes the battery health state calculation device to execute the following operations:
determining a battery attenuation curve of the vehicle to be charged according to the vehicle information; the battery attenuation curve comprising correspondence between battery attenuation information and battery usage time;
determining target attenuation information according to the time interval and the battery capacity attenuation curve;
and determining the target battery capacity according to the target attenuation information and the initial battery capacity.

In an alternative manner, the charging parameters include a charging current and charging time, and the SOC information includes a first SOC corresponding to the starting time of the target charging period and a second SOC corresponding to the end time of the target charging period for the vehicle to be charged; the executable instruction causes the battery health state calculation device to execute the following operations:
performing a calculation according to the charging current and the charging time to obtain a charging electric quantity corresponding to the target charging period;
determining the SOC change amount of the vehicle to be charged in the target charging period according to the first SOC and the second SOC;
and determining the battery health state of the vehicle to be charged according to the charging electric quantity, the SOC change amount, and the target battery capacity.

In an alternative manner, the executable instruction causes the battery health state calculation device to execute the following operations:
determining a product of the target battery capacity and the SOC change amount as a battery-received electric quantity;
and determining the battery health state according to a specific value of the charging electric quantity to the battery-received electric quantity.

In an alternative manner, the executable instruction causes the battery health state calculation device to execute the following operations:
determining whether the charging current meets a current threshold;
and if so, determining the second SOC according to a SOC charging current curve, wherein the SOC charging current curve comprises a correspondence between the SOC and the charging current, and the SOC charging current curve is determined according to the vehicle information.

In an alternative manner, the executable instruction causes the battery health state calculation device to execute the following operations:
determining the charging efficiency of the vehicle to be charged according to the vehicle information;
and performing a calculation on the charging efficiency, the charging current, and the charging time to obtain the charging electric quantity.

A computer-readable storage medium provided by an embodiment of the present invention acquires the SOC information of the vehicle to be charged and a charging parameter of the target charging period, and determines its battery health state according to the charging parameter and SOC information and the target battery capacity corresponding to the vehicle to be charged. Therefore, it can overcome the technical defect that the calculation efficiency of the battery health state is low due to the big data model or laboratory simulation adopted in the prior art, thereby improving the efficiency of the calculation of the battery health state.

An embodiment of the present invention provides a charging pile comprising the battery health calculation device.

A charging pile provided by an embodiment of the present invention acquires the SOC information of the vehicle to be charged and a charging parameter of the target charging period, and determines its battery health state according to the charging parameter and SOC information and the target battery capacity corresponding to the vehicle to be charged. Therefore, it can overcome the technical defect that the calculation efficiency of the battery health state is low due to the big data model or laboratory simulation adopted in the prior art, thereby improving the efficiency of the calculation of the battery health state.

In an alternative manner, the charging pile further comprises a VCI device for acquiring the vehicle information and the SOC information.

The charging pile provided by an embodiment of the present invention establishes communication with a vehicle to be charged via a VCI device, so as to acquire SOC information about the vehicle to be charged, and then determines its battery health state according to the charging parameter and SOC information about the target charging period and a target battery capacity corresponding to the vehicle to be charged, so as to overcome the technical defect that the calculation efficiency of the battery health state is low due to the big data model or laboratory simulation adopted in the prior art, thereby improving the efficiency of the calculation of the battery health state.

An embodiment of the present invention provides a battery health calculation apparatus for executing the battery health calculation method described above.

An embodiment of the present invention provides a computer program that can be called by a processor to cause a battery health calculation device to execute the battery health calculation method in any of the method embodiments described above.

An embodiment of the present invention provides a computer program product comprising a computer program stored on a computer-readable storage medium, the computer program comprising a program instruction which, when run on a computer, causes the computer to execute the battery health state calculation method in any of the method embodiments described above.

The algorithm or display provided herein is not inherently related to any particular computer, virtual system, or other devices. Various general-purpose systems may also be used with the teachings based on what is disclosed herein. According to the above description, the structure required to construct such a system is obvious. Furthermore, embodiments of the present invention are not directed to any particular programming language. It should be understood that the contents of the invention described herein can be realized by using various programming languages, and the description of the specific language is to disclose the best implementation mode of the invention.

The steps in the above embodiments are not to be construed as limiting the order of execution unless otherwise specified. The above is only a preferred embodiment of the present application, and is not intended to limit the scope of the patent of the present application. Any equivalent structure or equivalent process transformation made by using the contents of the description and accompanying drawings of the present application, or directly or indirectly applied to other related technical fields is similarly included within the scope of patent protection of the present application.

1. A battery health state calculation method applied to a charging device, the method comprising:
acquiring vehicle information of a vehicle to be charged in response to a charging start operation;
determining a target battery capacity of the vehicle to be charged according to the vehicle information;
acquiring, in response to a charging end operation, a charging parameter of the charging device and SOC information of the vehicle to be charged within a target charging period, the target charging period comprising a time period between the charging start operation and the charging end operation;
and determining a battery health state of the vehicle to be charged according to the charging parameter, the SOC information, and the target battery capacity.

2. The method according to claim 1, wherein the vehicle information comprises a VIN code, and the determining a target battery capacity of the vehicle to be charged according to the vehicle information comprises:
determining manufacturer information, vehicle type information, and production time of the vehicle to be charged according to the VIN code;
determining an initial battery capacity of the vehicle to be charged according to the manufacturer information, vehicle type information, and production time;
determining a time interval between the production time and time of the charging start operation;
and determining the target battery capacity according to the time interval, vehicle information, and initial battery capacity.

3. The method according to claim 2, wherein the determining the target battery capacity according to the time interval, vehicle information, and initial battery capacity comprises:
determining a battery attenuation curve of the vehicle to be charged according to the vehicle information, the battery attenuation curve comprising correspondence between battery attenuation information and battery usage time;
determining target attenuation information according to the time interval and the battery capacity attenuation curve;
and determining the target battery capacity according to the target attenuation information and the initial battery capacity.

4. The method according to claim 1, wherein the charging parameter comprises a charging current and charging time; the SOC information comprises a first SOC corresponding to a starting time of the target charging period and a second SOC corresponding to an end time of the target charging period of the vehicle to be charged; the determining a battery health state of the vehicle to be charged according to the charging parameter, the SOC information, and the target battery capacity comprises:
performing a calculation according to the charging current and the charging time to obtain a charging electric quantity corresponding to the target charging period;
determining SOC change amount of the vehicle to be charged in the target charging period according to the first SOC and the second SOC;
and determining the battery health state of the vehicle to be charged according to the charging electric quantity, the SOC change amount, and the target battery capacity.

5. The method according to claim 4, wherein the determining the battery health state of the vehicle to be charged according to the charging electric quantity, the SOC change amount, and the target battery capacity comprises:
determining a product of the target battery capacity and the SOC change amount as a battery-received electric quantity;
and determining the battery health state according to a specific value of the charging electric quantity to the battery-received electric quantity.

6. The method according to claim 4, wherein, before the determining SOC change amount of the vehicle to be charged in the target charging period according to the first SOC and the second SOC, the method comprises:
determining whether the charging current meets a current threshold;
and if so, determining the second SOC according to a SOC charging current curve, wherein the SOC charging current curve comprises a correspondence between the SOC and the charging current, and the SOC charging current curve is determined according to the vehicle information.

7. The method according to claim 4, before the performing a calculation according to the charging current and the charging time to obtain a charging electric quantity corresponding to the target charging period, further comprising:
determining a charging efficiency of the vehicle to be charged according to the vehicle information;
and performing a calculation on the charging efficiency, the charging current, and the charging time to obtain the charging electric quantity.

8. A battery health state calculation device, comprising: a processor, a memory, a communication interface, and a communication bus, the processor, the memory, and the communication interface completing communication with each other through the communication bus;
and the memory being used for storing at least one executable instruction that causes the processor to execute a method comprising steps of:
acquiring vehicle information of a vehicle to be charged in response to a charging start operation;
determining a target battery capacity of the vehicle to be charged according to the vehicle information;
acquiring, in response to a charging end operation, a charging parameter of the charging device and SOC information of the vehicle to be charged within a target charging period, the target charging period comprising a time period between the charging start operation and the charging end operation;
and determining a battery health state of the vehicle to be charged according to the charging parameter, the SOC information, and the target battery capacity.

9. A computer-readable storage medium, characterized by storing therein at least one executable instruction which, when run on a battery health state calculation device, causes the battery health state calculation device to execute a method comprising steps of:
acquiring vehicle information of a vehicle to be charged in response to a charging start operation;
determining a target battery capacity of the vehicle to be charged according to the vehicle information;
acquiring, in response to a charging end operation, a charging parameter of the charging device and SOC information of the vehicle to be charged within a target charging period, the target charging period comprising a time period between the charging start operation and the charging end operation;
and determining a battery health state of the vehicle to be charged according to the charging parameter, the SOC information, and the target battery capacity.

10-11. (canceled)

12. The device according to claim 8, wherein the vehicle information comprises a VIN code, when the processor executes the step of determining a target battery capacity of the vehicle to be charged according to the vehicle information, the processor specifically executes steps of:
determining manufacturer information, vehicle type information, and production time of the vehicle to be charged according to the VIN code;
determining an initial battery capacity of the vehicle to be charged according to the manufacturer information, vehicle type information, and production time;
determining a time interval between the production time and time of the charging start operation;
and determining the target battery capacity according to the time interval, vehicle information, and initial battery capacity.

13. The device according to claim 12, wherein when the processor executes the step of determining the target battery capacity according to the time interval, vehicle information, and initial battery capacity, the processor specifically executes steps of:
determining a battery attenuation curve of the vehicle to be charged according to the vehicle information, the battery attenuation curve comprising correspondence between battery attenuation information and battery usage time;
determining target attenuation information according to the time interval and the battery capacity attenuation curve;
and determining the target battery capacity according to the target attenuation information and the initial battery capacity.

14. The device according to claim 8, wherein the charging parameter comprises a charging current and charging time; the SOC information comprises a first SOC corresponding to a starting time of the target charging period and a second SOC corresponding to an end time of the target charging period of the vehicle to be charged; when the processor executes the step of determining a battery health state of the vehicle to be charged according to the charging parameter, the SOC information, and the target battery capacity, the processor specifically executes steps of:
performing a calculation according to the charging current and the charging time to obtain a charging electric quantity corresponding to the target charging period;
determining SOC change amount of the vehicle to be charged in the target charging period according to the first SOC and the second SOC;
and determining the battery health state of the vehicle to be charged according to the charging electric quantity, the SOC change amount, and the target battery capacity.

15. The device according to claim 14, wherein when the processor executes the step of determining the battery health state of the vehicle to be charged according to the charging electric quantity, the SOC change amount, and the target battery capacity, the processor specifically executes steps of:
determining a product of the target battery capacity and the SOC change amount as a battery-received electric quantity;
and determining the battery health state according to a specific value of the charging electric quantity to the battery-received electric quantity.

16. The device according to claim 14, wherein before when the processor executes the step of determining SOC change amount of the vehicle to be charged in the target charging period according to the first SOC and the second SOC, the processor specifically executes steps of:
determining whether the charging current meets a current threshold;
and if so, determining the second SOC according to a SOC charging current curve, wherein the SOC charging current curve comprises a correspondence between the SOC and the charging current, and the SOC charging current curve is determined according to the vehicle information.

17. The device according to claim 14, wherein before when the processor executes the step of d performing a calculation according to the charging current and the charging time to obtain a charging electric quantity corresponding to the target charging period, the processor specifically executes steps of:
determining a charging efficiency of the vehicle to be charged according to the vehicle information;
and performing a calculation on the charging efficiency, the charging current, and the charging time to obtain the charging electric quantity.
